(19) United States
(12) Patent Application Publication
(10) Pub. No.: US 2005/0249249 A1
(43) Pub. Date: Nov. 10, 2005

(54) Wavelength division multiplexing using carbon nanotubes

(76) Inventor: John W. Pettit, Rockville, MD (US)

Correspondence Address: BLANK ROME LLP, 600 NEW HAMPSHIRE AVENUE, N.W., WASHINGTON, DC, 20037, US

(21) Appl. No.: 11/024,409

(22) Filed: Dec. 30, 2004

Related U.S. Application Data
(60) Provisional application No. 60/533,150, filed on Dec. 31, 2003.

(51) Int. Cl. H01S 3/10

(52) U.S. Cl. 372/20; 398/43

(57) ABSTRACT

In a narrow band light source, the optical emission wavelength is adjusted and stabilized based upon one or more carbon nanotube ambipolar FETs where electrons and holes combine to emit light at the nanotube bandgap and a component adapted to change and control the nanotube bandgap by physical distortion, bending or chemical and electrical effects. A feedback loop can be included to stabilize or scan the wavelength. In a network using such light sources, some of the sources can be held in reserve in case others fail.

### REFERENCE TO RELATED APPLICATION

The present application claims the benefit of U.S. Provisional Patent Application No. 60/533,150, filed Dec. 31, 2003, whose disclosure is hereby incorporated by reference in its entirety into the present disclosure.

### FIELD OF THE INVENTION

The present invention is directed to a tunable light source for wavelength division multiplexing and more particularly to such a tunable light source in which wavelength is controlled by controlling a carbon nanotube. The present invention is further directed to an optical communication network using such tunable light sources.

### DESCRIPTION OF RELATED ART

Wavelength Division Multiplexing (WDM) is a very important technique used in fiber optic systems that greatly increases the information handling capabilities of an optical fiber. An optical fiber has the ability to carry light over large distances in a manner that allows the light to be transmitted and reliably detected at very high data rates. Wavelength Division Multiplexing is a technique where multiple optical signals are employed simultaneously by using light of different wavelengths. Each wavelength has roughly the same ability to handle data at a high rate and when multiple wavelengths are used the data handling capability of the fiber are multiplied.

In order to implement a WDM system, a technique to generate light at the various wavelengths and couple them into the fiber is needed, and a technique to separate out and detect the light at these wavelengths is also needed. Each wavelength in a WDM system is called a channel and the channels may be widely spaced, termed coarse WDM, or they may be tightly spaced, termed dense WDM. The wavelength spacing between adjacent channels in a WDM system is determined by factors such as the wavelength stability and wavelength bandwidth of the light sources, the precision of the optical combiners and splitters and the overall system performance requirements. The closer the channels are to one another, the greater the chance of cross talk and interference, which require the use of more precise components, which drive up the costs and complexity of the system.

The light source is an extremely important element of the WDM system, as it sets the limit for the fundamental performance capabilities of the system. Often the design and specification of the entire WDM system are dictated by the characteristics and qualities of the light source employed. Semiconductor lasers are the most desirable light sources for many WDM systems, and in particular vertical cavity surface emitting lasers (VCSEL) devices have gained popularity due to their low cost, size and ability to be fabricated in arrays to create multiple channels. VCSEL devices have the advantage of a narrow optical bandwidth, excellent beam characteristics and simpler electrical drive and interface requirements as compared to the more familiar edge emitting lasers that are used in, for instance, laser pointer devices.

The process to fabricate semiconductor lasers that emit light at the various desired optical wavelengths is rather complicated. The solid-state medium in a semiconductor laser will have optical gain over an optical bandwidth of something in the range of 60 nanometers. The resonant cavity surrounding the gain medium selects a specific wavelength for amplification and this is determined fundamentally by the length of the cavity. Therefore, when making semiconducting lasers for this purpose, production lines have to be set up that create different cavity lengths in order to yield the desired output wavelengths. Some companies have proprietary means to create devices with multiple VCSEL lasers of differing cavities and therefore output wavelengths, but more often multiple dedicated production lines are used to create VCSEL devices that work at numerous specific optical wavelengths.

Fiber optic WDM networks are very desirable for use in military and even commercial aircraft for primary flight control, navigation, communication, aviation and other purposes. The US Air Force has an active “Fly-by-Fiber” program whose objective is to achieve the control of primary flight control surfaces and key elements through a fiber optic WDM system. The US Navy wishes to utilize fiber optic networks for communication purposes aboard certain of its aircraft. Whereas initial Fly-by-Fiber systems will be digital in that they carry only digital data, communication, aviation and navigation fiber optic systems will need to carry analog data. In the analog domain, the dynamic range, linearity, fidelity and other such qualities of the data are much more important than they are in digital systems.

In analog communication systems, the concept of a spurious signal free dynamic range is a key performance specification. Spurious signals are unwanted signals generated within a system due to a number of causes, such as parasitic resonances and nonlinearities. When these spurious signals, or “spurs” as they are often called, are in a system, they lower the dynamic range of the system for the following reason. Since spurs cannot be distinguished from real signals, the detection threshold for real signals has to be set higher than the highest spur in the system. Since this elevated detection threshold is almost always higher than the noise floor, where the detection threshold would normally be set, a portion of the otherwise usable dynamic range of the system is lost, thus reducing the dynamic range. As a result, real signals that are wanted to be detected are now required to be large enough to rise above the spurious signal level in order to be detected, and the system's sensitivity has been lowered as compared to what is otherwise could be.

VCSEL devices are severely limited in terms of the spur free dynamic range that they can attain, which places a significant limitation on their use in analog fiber optic systems. This is due to the physics of the device and is inherent in their operation. A means of dealing with this is to operate the VCSEL at a continuous power level and then modulate its output with a separate optical modulation device, simply termed a modulator. This adds the cost and complexity of a modulator, and even these devices have performance limitations that are not desirable.

In an unrelated field of endeavor, carbon nanotubes have been shown by researchers at IBM T. J. Watson Research Laboratories, under the direction of Phadeon Avouris, to emit light under certain conditions [Reference 1]. In this research, the carbon nanotube is operated as an amibpolar FET, meaning that both holes and electrons are being conducted within the nanotube, as compared to only electrons in an N-channel device or holes in a P-channel device. These electrons and holes combine in the channel and create light with high efficiency, the IBM researchers found. The light wavelength is directly related to the bandgap of the carbon nanotube.

In yet another area of unrelated research, it has been found that the bandgap of carbon nanotubes can be modified or controlled by external action, such as compressing nanotubes in the radial direction [Reference 2-3] or twisting or distorting them. Such action stretches the carbon to carbon bonds of the otherwise planar sp² hybrid covalent bond between the carbon atoms and the bandgap is modified as a result. In several research papers, radial distortion of nanotubes was shown to make the bandgap of semiconducting nanotubes get smaller and then close, making them metallic, and then reopen upon further distortion, making them semiconducting again. Authors of these papers have seen this bandgap modulation effect to be a very useful phenomenon and have termed it “bandgap engineering” and predict that this effect will be useful for many applications.

However, the art neither teaches or suggests a way to use carbon nanotubes to improve WDM. Nor does the art even provide motivation to do so.

### SUMMARY OF THE INVENTION

It will be seen from the above that a need exists in the art to provide a large dynamic range while overcoming the above-noted problems of spur.

It is therefore an object of the invention to provide an effective light source for WDM systems which also has the qualities of large spur-free dynamic range.

That and other objects are met by a narrow band light source whose optical emission wavelength can be adjusted and stabilized based upon one or more carbon nanotube ambipolar FETs where electrons and holes combine to emit light at the nanotube bandgap and a component adapted to change and control the nanotube bandgap by physical distortion, bending or chemical and electrical effects.

A combination of the phenomena of light emission from a carbon nanotube FET operated in ambipolar mode and the bandgap engineering concept gives rise to the invention of a tunable light source with high spur free dynamic range for use in WDM fiber optic systems in the following way. A carbon nanotube ambipolar transistor can be used to create the light for the fiber optic system and is small enough to even be embedded within the fiber itself. The wavelength of its emission can be made to be precisely what is necessary for any given WDM channel by the application of the appropriate bandgap modifying effect, such as radial distortion, in the correct amount to yield the desired wavelength output.

The light output intensity of the carbon nanotube FET is modulated by the information containing input signal by applying this signal to either end of the nanotube or to the nanotube FET gate, which is typically the substrate. This is analogous to using an ordinary FET in a conventional signal amplification or modulation circuit, only in this case the output is light that is coupled into the optical fiber.

There are numerous advantages to this invention. First, no additional light modulator device is necessary, since the nanotube itself creates the light to be fed into the optical fiber with high dynamic range of its light output. Second, multiple identical copies of a single device can be designed and constructed, and each one can be individually “tuned” to create the output optical wavelength for its respective WDM channel. Furthermore, the optical wavelength can be controlled and stabilized against factors such as temperature drift by monitoring the wavelength and employing a feedback signal to the bandgap modulation mechanism, which, for instance, could be the degree of radial compression. As a result, a single device would only have to be manufactured, and it could simply be adjusted to become the light source for any WDM channel. With the VCSEL approach, a different VCSEL is needed for each WDM channel that is desired in the system. This increases system cost and complexity and repair and maintenance burdens to stock all varieties of VCSEL devices used in a system.

The gate of a nanotube FET can be controlled optically as described in U.S. patent application Ser. No. 11/______, filed Dec. 30, 2004, by John Pettit, entitled “Optically controlled electrical switching device based on wide bandgap semiconductors” (attorney docket no. 000049-00116), whose disclosure is hereby incorporated by reference in its entirety into the present application. This creates some very interesting possibilities and uses. For instance, an optical signal at one wavelength can be both amplified and converted to another wavelength by this technique. The optical signal to be converted is directed to the gate or gate substrate or to some photo-conductive material as taught in the above referenced application. This light then controls the FET action of the light source described in this present invention, and the light source emits light in a manner that is controlled by the input light signal, but at a wavelength that is determined by its own bandgap under bandgap control as described in this application. This feature may be used as a simple repeater or light amplification function or as a wavelength shifting function, or both. In a general sense this allows optical control of optical systems, and is a significant step toward full optical operation of systems, which is an important goal of the US Air Force “Fly-by-Fiber” program.

In aircraft systems, it is desirable to employ fiber optic WDM systems as widely as possible. However, the fiber optic networks are not presently compatible and separate networks are presently in use. This invention that has the qualities for analog and digital use allows the merging of the various sub-networks into one overall, interoperable network. This is a very desirable feature as it integrates the various functions of an aircraft and allows more complete control of all aircraft functions.

Embodiments of the present invention include, but are not limited to, the following:

A light source as described above where a feedback control function is used to both set the output of the device to the desired center optical wavelength and further to stabilize the output wavelength against drift and fluctuations.

A light source as described above where the wavelength setpoint is varied and the wavelength control loop follows this setpoint so as to create a modulation of the wavelength, or a sweep of the wavelength or other wavelength variation in time that is desired.

A light source as described above that can be used in a fiber optic wavelength division multiplexing, WDM optical network.

A light source as described above where multiple such light sources are used to create the needed optical wavelengths to comprise the set of wavelengths in the WDM network.

A light source as described above where the nanotubes are embedded within on onto the surface of an optical fiber.

A light source as described above where the input signal is applied to either the ends of the nanotube, comprising the source and drain contacts, or to the gate of the nanotube FET.

A light source as described above where the input signal controls the amount of light output at the wavelength that is determined by the nanotube bandgap, which itself is being controlled by techniques disclosed above.

A light source as described above that achieves large usable dynamic range as a result of the comparably linear nature of the light output over a large range with no spurious signals to diminish the dynamic range.

A fiber optic WDM network that employs multiple light sources as described above to create the channels of the WDM network that are combined together into the optical fiber.

A fiber optic WDM network as described above where extra light sources are incorporated into the system that are held in reserve until needed and are then set to operate at the required wavelength.

A fiber optic WDM network that has logic to detect that a WDM channel has failed or is not functioning properly and shuts this defective channel down and activates one of the reserve channels to operate in its place.

A fiber optic network using a light source as described above that is used in aircraft control, communication, navigation, aviation, and other applications.

A fiber optic network that uses a light source as described above to carry analog information including voice, video, data, radar, sonar, altitude or positioning data.

A fiber optic network that merges separate sub-networks together into one interoperable network, where the sub-networks comprise a flight control network, a communications network, a navigation network, a fire control network and other variously defined sub-networks.

An analog optical network using a light source as described above where the information is encoded by direct modulation of the nanotube ambipolar FET, either through its end contacts or through its gate, without the need for a separate modulation device.

A light source as described above where the gate signal itself is optically controlled so as to create a light source that is driven by another light source or a light amplifier or wavelength shifter function, when the bandgap of the nanotube emits at a different wavelength from the wavelength of the light controlling the nanotube's gate.

Optically controlling the gate of a light source as described above by optically creating charge acting near the nanotubes surface that modify the Fermi level in the nanotube through the “quantum capacitance”.

Optically controlling the operating characteristics of an optical system, such as its output wavelength, output signal strength and so forth.

### REFERENCES

1. J. A. Misewich et. al. “Electrically Induced Optical Emission from Carbon Nanotube FET”, Science Volume 300, 2 May 2003, Pages 783-786.
2. O. Gulseren et. al. “Reversible Band Gap Engineering in Carbon Nanotubes by Radial Deformation”, Condensed Matter 0203226 v1, 11 Mar. 2002
3. S. Peng and K. Cho “Nano Electro Mechanics of Semiconducting Carbon Nanotube”, Journal of Applied Mechanics, Volume 69, July 2002, pages 451-453

### BRIEF DESCRIPTION OF THE DRAWINGS

A preferred embodiment of the present invention will be set forth in detail with reference to the drawings, in which:

FIG. 1 is a schematic diagram showing a tunable light source according to the preferred embodiment;

FIG. 1A is a schematic diagram showing a modification of the tunable light source of FIG. 1; and

FIG. 2 is a block diagram showing a WDM optical network using the tunable light source of FIG. 1.

### DETAILED DESCRIPTION OF THE PREFERRED EMBODIMENT

A preferred embodiment of the present invention and variations thereon will be set forth in detail with reference to the drawings, in which like reference numerals refer to like elements throughout.

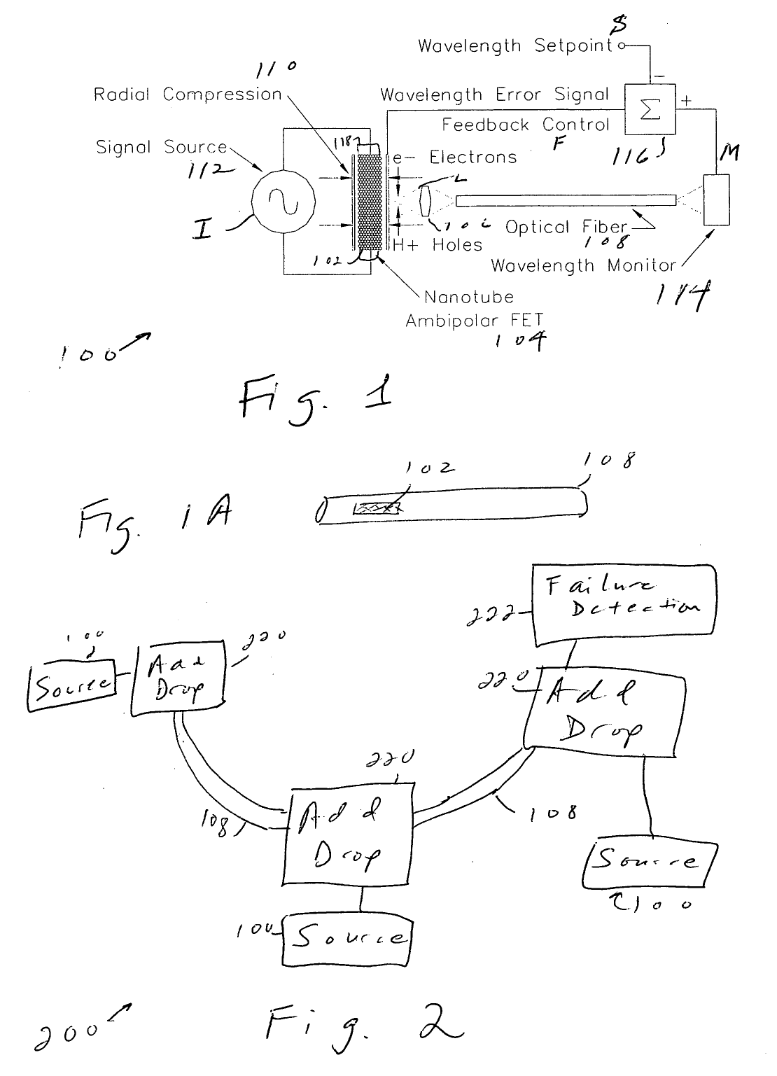

A tunable light source according to the preferred embodiment is shown in FIG. 1 as 100. A carbon nanotube 102, or bundle with many nanotubes acting in parallel, is formed into an ambipolar FET (field effect transistor) 104, as described in the literature by the IBM research [Reference 1]. In an ambipolar FET, both electrons and holes are made to flow, and they combine and release their energy by emitting an optical photon whose energy and wavelength correspond to the nanotube bandgap. This process is indicated in FIG. 1 by the electrons e⁻ flowing down and the holes H⁺ flowing up to meet near the center of the nanotube 102 and emit light L. This light L is then directed via a lens 106 into an optical fiber 108. In various embodiments, a lens 106 may or may not be used, depending on the design of the system.

The nanotube 102 may be embedded within the optical fiber 108 in another embodiment of this invention, as shown in FIG. 1A. Otherwise, that embodiment can be constructed like the embodiment of FIG. 1.

The nanotubes 102 undergo radial compression by a radial compression mechanism 110 to modulate their bandgap, as has been shown in the research literature to take place in nanotubes when the nanotubes are distorted. This action slightly compresses the nanotubes 102 in the radial direction. This compression causes the nanotubes 102 to become somewhat elliptical in cross section.

Considering the nanotube cross section as an ellipse for the purpose of explaining the bandgap modulation effect, an ellipse can be characterized by its major and minor axes. A circle is a limiting example of an ellipse where the two axes are equal. It has been shown in the literature [Reference 2-3] that when nanotube has been flattened into an ellipse where the ratio of the two axes reach a value of about 0.8, or in other words the nanotubes have been flattened by something in the neighborhood of 20%, the nanotube bandgap completely disappears, and the nanotube becomes metallic. This figure of 20% flattening is representative of one type of nanotube, such as an 8,0 nanotube, where these two numbers are used in the customary in nanotube literature to designate the indices of the nanotube. Other nanotubes with differing indices will demonstrate bandgap modulation effects at differing degrees of radial compression, but the principle remains the same.

For WDM applications, the amount of change in nanotube bandgap needed to create the different optical wavelengths and to affect wavelength stabilization and control is only a few percent. When the bandgap disappears, the optical transition also vanishes, so the amount of nanotube radial distortion needed is only a very small amount of the 20% needed to completely close the bandgap. Typically only a couple percent of nanotube flattening will be needed to make the nanotube bandgap cover the desired wavelength range for WDM applications.

Nanotube flattening is only one means to affect what has been termed “bandgap engineering”. In other embodiments, various regions of a single nanotube could be made to undergo differing amounts of distortion to give rise to differing bandgaps within a nanotube and have effects such as multiple wavelengths emitting from a single nanotube and other interesting phenomena.

The system 100 includes a wavelength monitor 114. This can be a simple interference filter or similar device that monitors the wavelength drift of the optical emissions from the nanotube by measuring the amount of signal received falling to either side of a defined wavelength passband and outputs a monitor signal M. Many techniques are known in the art to monitor optical wavelength that can be used here.

An input signal called the Wavelength Setpoint S is applied along with the wavelength monitor signal M to a control unit 116 that first computes the wavelength error signal, which is the difference between the wavelength setpoint and the monitor signals, namely, S−M, in fashion well known in the art for feedback control. This summation function is denoted by the Greek symbol capital sigma, Σ, which is the customary symbol for this function in control theory. From this error signal is derived a control signal by means of an optimal control transfer function, which is well known in the art and is not detailed here. Suffice it to say that from the wavelength error signal a suitable feedback control signal F is obtained with the necessary time constants, phase margins and gain factors so that this signal can be applied to the mechanism 110 that creates the radial compression on the nanotubes. This signal applied to the radial compression mechanism 110 commands this mechanism 110 to alter the amount of compression and this alters the wavelength output of the nanotube, as explained above, so that the control loop is stable and the error signal is reduced to zero as nearly as possible. Optimum wavelength control is thereby achieved.

This wavelength control signal is applied to the structure that creates the radial compression in the manner of negative feedback with appropriate gain and phase margin so as to create a fast acting stable control loop that will keep the optical emission centered at the desired optical wavelength. Furthermore, this feedback signal could even be used as a control signal to affect a controlled change in the optical wavelength, such as a sweeping or saw-tooth waveform, which could have some benefits in certain applications.

In FIG. 1, the many details of an optical WDM network have not been shown so that the main concepts of this invention can be emphasized. In such a network 200, as shown in FIG. 2, the optical fiber 108 would typically have many add and drop points 220 where signals are brought into or taken out of the fiber network. Also, multiple nanotube light sources 100 operating at different optical wavelengths would normally be employed in a practical fiber optic WDM network 200. An advantage of this invention is that each of these multiple nanotube light sources 100 would be identical, but would each have its own wavelength setpoint input. The degree of radial compression created by the control loop would be different on each device 100 so that each device 100's optical output is centered at its respective wavelength in order to comprise the complete set of wavelengths needed for the particular WDM network 200. Of course, the WDM network 200 can include the light sources 100 of FIG. 1, the modification of FIG. 1A, or any other variation of the light sources of the present invention.

This is an enormous advantage in terms of simplicity and reliability in field operation for a WDM network 200. One could even have extra nanotube light sources 100 of the kind described in this invention fitted into the WDM network 200 that are not used initially, but are kept in reserve in the case of a failure. Since any one of the nanotube light source of this invention can be directed to output at any of the wavelengths of the WDM system, when failure detection logic 222 in the network detects that any given light source has failed, the failure detection logic 222 could turn on one of the reserve light sources, and set it to operate at the wavelength of the failed device. This feature is of great benefit to military networks that need high degrees of reliability in severe environments.

Returning to FIG. 1, the signal I containing the information to be transmitted through the WDM network is supplied via the signal source 112. This signal source 112 is shown being applied to the ends of the nanotube FET 104, as if to apply the signal I to the source and drain contacts of a conventional FET. Depending on the desired electrical design, the signal I could also be applied to the gate of the FET 104. In the case of the nanotube FET 104, the gate would typically be the surface underneath the insulating oxide layer. Thus, the intensity of the light L is controlled, and a separate modulator is not needed. Alternatively, the information signal could be applied to a substrate 118 forming a gate of the nanotube FET 104.

While a preferred embodiment has been set forth in detail above, those skilled in the art who have reviewed the present disclosure will readily appreciate that other embodiments can be realized within the scope of the invention. Some such embodiments have already been mentioned above. Therefore, the present invention should be construed as limited only by the appended claims.

1. A tunable narrow-band light source, the source comprising:
an ambipolar field effect transistor comprising one or more carbon nanotubes having a nanotube bandgap, the one or more carbon nanotubes emitting light at a wavelength determined by the nanotube bandgap; and
a bandgap changing device for changing the nanotube bandgap to change the wavelength at which the light is emitted.

2. The source of claim 1, wherein the bandgap changing device comprises a device for radially compressing the one or more carbon nanotubes.

3. The source of claim 1, further comprising an optical fiber for receiving and transmitting the light.

4. The source of claim 3, wherein the one or more carbon nanotubes are embedded in the optical fiber.

5. The source of claim 1, further comprising a feedback loop for detecting the wavelength at which the light is emitted, comparing the wavelength at which the light is emitted to a wavelength set point to derive a feedback control signal, and applying the feedback control signal to the bandgap changing device to correct the wavelength at which the light is emitted.

6. The source of claim 5, wherein the feedback control signal is determined in accordance with a difference between the wavelength set point and the wavelength at which the light is emitted.

7. The source of claim 5, wherein the wavelength set point is changed to change the wavelength at which the light is emitted.

8. The source of claim 1, further comprising a signal source, in communication with the ambipolar field effect transistor, for supplying an information signal to the ambipolar field effect transistor to control the ambipolar field effect transistor to modulate an intensity at which the light is emitted in accordance with the information signal.

9. The source of claim 8, wherein the signal source supplies the information signal to ends of the at least one carbon nanotube.

10. The source of claim 8, wherein the signal source supplies the information signal to a gate of the ambipolar field effect transistor.

11. A wavelength division multiplexing optical network for transmitting information as optical signals, the network comprising:
at least one optical fiber on which the optical signals are transmitted;
a plurality of add and drop points along the at least one optical fiber for allowing the optical signals to enter and leave the at least one optical fiber; and
a plurality of tunable narrow-band light sources in communication with the optical fiber through the add and drop points, the plurality of tunable narrow-band light sources emitting the optical signals, wherein each of the plurality of tunable narrow-band light sources comprises:
an ambipolar field effect transistor comprising one or more carbon nanotubes having a nanotube bandgap, the one or more carbon nanotubes emitting light at a wavelength determined by the nanotube bandgap;
a bandgap changing device for changing the nanotube bandgap to change the wavelength at which the light is emitted; and
a signal source, in communication with the ambipolar field effect transistor, for supplying an information signal to the ambipolar field effect transistor to control the ambipolar field effect transistor to modulate an intensity at which the light is emitted in accordance with the information signal to form one of the optical signals.

12. The network of claim 11, wherein the plurality of tunable narrow-band light sources comprises:
a first subplurality of tunable narrow-band light sources which are in use in the network; and
a second subplurality of tunable narrow-band light sources which are held in reserve in case at least one of the first subplurality of tunable narrow-band light sources fails.

13. The network of claim 12, further comprising failure detection logic for detecting when one of the first subplurality of tunable narrow-band light sources fails and for controlling one of the second subplurality of tunable narrow-band light sources to operate in place of the failed one of the first subplurality of tunable narrow-band light sources.

14. The network of claim 13, wherein said one of the second subplurality of tunable narrow-band light sources which operates in place of the failed one of the first subplurality of tunable narrow-band light sources is tuned to operate at a wavelength equal to a wavelength of the failed one of the first subplurality of tunable narrow-band light sources.

15. The network of claim 11, wherein the information comprises analog information.

16. The network of claim 15, wherein the information further comprises digital information.
